(19) United States
(12) Patent Application Publication
(10) Pub. No.: US 2007/0131910 A1
(43) Pub. Date: Jun. 14, 2007

(54) Conductive polymer

(75) Inventors: Abraham Daniel, Galashiels (GB); Alexander Fraser Fotheringham, Clovenfords (GB)

Correspondence Address: YOUNG & BASILE, P.C., 3001 WEST BIG BEAVER ROAD, SUITE 624, TROY, MI, 48084, US

(73) Assignee: HERIOTWATT UNIVERSITY, Edinburgh (GB)

(21) Appl. No.: 10/575,743

(22) PCT Filed: Oct. 7, 2004
(86) PCT No.: PCT/GB04/04244

§ 371 Date: Nov. 16, 2006

(30) Foreign Application Priority Data
Oct. 10, 2003 (GB) 0323733.6

(51) Int. Cl. H01B 1/12; H01L 51/50

(52) U.S. Cl. 252/500; 525/55; 428/419; 428/500; 428/917; 313/503; 313/506; 257/40; 257/E51.03

(57) ABSTRACT

This invention relates to an intrinsically conducting polymer (ICP), a plastics based electrode and a method for making such an electrode. In particular, the plastics based electrode comprises a plastic strip of cellulose acetate acting as a substrate with a thin coating of intrinsically conducting poly (3,4-ethylenedioxythiophene) and poly (4-styrnesulphonate) (i.e. PEDOT/PSS) polymer comprising an amount of vinylacetate/ethylene copolymer. The plastics based electrode may be used in apparatus for the detection of dental caries.

### FIELD OF THE INVENTION

This invention relates to an intrinsically conducting polymer (ICP), a plastics based electrode and a method for making such an electrode. In particular, the plastics based electrode comprises a strip of plastic made from a suitable material with the mechanical properties which allow the strip to be thin enough to fit between teeth but remaining stiff enough to prevent break up of the conducting polymer due to over-flexing. These materials may be either man made e.g. cellulose acetate, polypropylene, nylon etc or a biopolymer produced from renewable resources e.g. poly-lactic acid, poly-glycollic acid etc or any copolymer thereof, acting as a substrate with a thin coating of intrinsically conducting poly (3,4-ethylenedioxythiophene) and poly (4-styrenesulphonate) (i.e. PEDOT/PSS) polymer comprising an amount of vinylacetate/ethylene copolymer. The plastics based electrode may be used in apparatus for the detection of dental caries.

### BACKGROUND OF THE INVENTION

Certain polymers can be changed from being electrically insulating to conductive by a simple oxidation process. As these polymers are electrically conductive without the need of using filler materials, such as carbon particles and metallic fibres, these polymers are commonly known as intrinsically conducting polymers (ICPs). The conductive nature of ICPs comes from the conjugated electronic system of alternating single and double bonds in the backbone of the polymers.

ICPs combine the electronic and optical properties of metals and semiconductors while retaining the processing advantages of polymers; making ICPs suitable for various applications [1-3] such as antistatic and magnetic coatings, thin solid films, modified electrodes, batteries, sensors, actuators, ion-exchange materials and molecular devices.

The chemical structure of PEDOT/PSS is shown below:

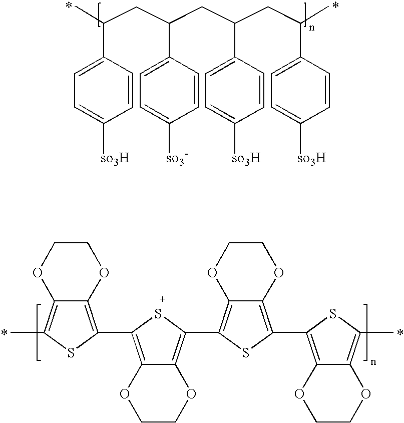

PEDOT/PSS is a highly conjugated polymer with many advantageous properties such as good thermal stability [4] in its oxidised state (i.e. doped form), high electrical conductivity [5] and excellent film formability [6]. However, there are significant disadvantages to PEDOT/PSS polymers which limit the scope of their application such as:
1. Pristine films cast from PEDOT/PSS exhibit poor mechanical properties (i.e. they are weak and brittle); and
2. PEDOT/PSS coatings exhibit very poor adhesion on plastic substrates due to the extensive conjugation in the main chain structure of the polymer resulting in increased chain stiffness and exfoliation of the coating.

It is an object of at least one aspect of the present invention to obviate or at least mitigate at least one or more of the aforementioned problems.

It is a further object of the present invention to provide a plastics based electrode which has good mechanical properties.

### SUMMARY OF THE INVENTION

According to a first aspect of the present invention there is provided an intrinsically conducting polymer (ICP) blend obtainable by adding:
a. a mixture of poly (3,5-ethylenedioxythiophene) and poly(4-styrenesulphonate) (i.e. PEDOT/PSS); to
b. a copolymer of vinylacetate and ethylene to thereby form the intrinsically conducting polymer (ICP) blend.

By intrinsically conducting polymer is meant a polymer which is electrically conductive without the need of using filler materials such as carbon particles and metallic fibres.

Typically, the viscosity of the PEDOT/PSS may be about 60 to about 100 mPa·s.

The amount of PSS present may be in excess of the amount of PEDOT. Conveniently, the ratio of PEDOT:PSS ranges from about 1:1.1 to about 1:5 or from about 1:1.3 to about 1:2 or may preferably be about 1:2.5.

The PEDOT/PSS may be in a liquid form and may have a concentration of about 1-2% by weight, about 1-10% by weight or about 3% by weight.

Conveniently, the PEDOT/PSS may be dissolved in a solvent such as water.

Typically, the ratio of vinylacetate:ethylene may be about 80:20. The particle size of the vinylacetate: ethylene mixture may be about 0.1-10 microns, 0.1-5 microns, 0.3-3.0 microns or about 0.3-1.2 microns. The viscosity of the vinylacetate:ethylene copolymer may be about 1,000-40,000 mPa·s, about 1-20,000 mPa·s, about 14,000 mPa·s or about 2,500 mPa·s. The vinylacetate:ethylene copolymer mixture may be acidic and may have a pH of about 2-6, about 3-5 or about 4.25.

Prior to mixing the PEDOT/PSS and the copolymer of vinylacetate and ethylene, the PEDOT/PSS may be mixed with an acid such as a carboxylic acid. The carboxylic acid may, for example, be selected from any C₁-C₂₀ carboxylic acid. Typically, the carboxylic acid may be any of methanoic acid, ethanoic acid, propanoic acid, butanoic acid, pentanoic acid, hexanoic acid, heptanoic acid and octanoic acid.

Conveniently, the ICP formed by mixing the PEDOT/PSS and the copolymer of vinylacetate and ethylene may form a substantially homogenous blend.

According to a second aspect of the present invention, there is provided a coated product wherein the coated product comprises a substrate with a coating of an intrinsically conducting polymer (ICP) blend comprising PEDOT/PSS and a copolymer of vinylacetate and ethylene according to the first aspect.

The coating is found to adhere strongly to the substrate, has good mechanical stability and is resistant to exfoliating.

The substrate may be made from any suitable material with the mechanical properties which allows the coated product to be thin enough to fit between teeth but remaining stiff enough to prevent break-up of the ICP due to over-flexing.

Typically, the substrate may be man made such as cellulose acetate, polypropylene, nylon or a biopolymer produced from renewable resources such as poly-lactic acid, poly-glycollic acid, or any copolymer thereof.

Conveniently, the coating may have a thickness of about 0.001 to 0.5 mm or about 0.01 to 0.1 mm. In particular, the thickness of the coating may be about 0.02, 0.03 and 0.04 mm.

Typically, the resistance of a coated part of the coated substrate may be about 0.1 to 500 k-ohm.

The coated substrate may be treated with a metal salt solution dissolved in aqueous acid. The metal salt solution may, for example, be magnesium sulphate. The concentration of the salt solution may be about 0.01 to 5 M, about 0.05 to 1 M or about 0.1 M. The aqueous acid may, for example, be a short chain carboxylic acid such as formic acid. The volume ratio of the carboxylic acid such as formic acid and water may, for example, be about 1:1 to 1:4.

The treated coated substrate may then be rinsed successively with water to remove excess salt, followed by ethanol and acetone. The substrates were finally dried in an oven at about 40° C.

Treating the coated substrate with a metal salt solution dissolved in aqueous acid has the effect of ‘fine tuning’ the surface and decreases the surface resistance to about less than 5 k-ohms, less than 1 k-ohms or less than about 0.5 k-ohms. The treated surface therefore has improved conducting properties.

According to a third aspect of the present invention there is provided a method of forming a coated substrate wherein coating material is formed by adding PEDOT/PSS to a copolymer of vinylacetate and ethylene to form an intrinsically conducting polymer (ICP) blend according to the first aspect and depositing the intrinsically conductive polymer (ICP) blend onto a substrate.

Typically, the ICP blend may be deposited by any suitable means such as spraying, brushing, or using a dropper such as a syringe.

According to a fourth aspect of the present invention there is provided an electrode comprising a coated substrate wherein the coating of the coated substrate is an intrinsically conducting polymer (ICP) blend comprising PEDOT/PSS and a copolymer of vinylacetate and ethylene according to the first aspect.

The electrode may be used in a wide range of applications such as:

(1) dental apparatus for the detection of caries;

(2) a thin and intermediate layer between an anode of, for example, indium-tin-oxide (ITO), and a light emitting layer of organic polymers used widely in molecular devices—the PEDOT/PSS copolymer blends may polarise the otherwise rough ITO surface, modify the wetting properties of the ITO surface for subsequent organic layer deposition and increase the anode work function, thus facilitating hole injection, and

(3) PEDOT/PSS copolymer blends can be deposited on many fabrics, both natural and synthetic resulting in novel conductive composite materials.

According to a fifth aspect of the present invention there is provided dental apparatus for the detection of dental caries comprising:

at least one probe electrode comprising a coated substrate wherein the coating of the coated substrate is an intrinsically conducting polymer of PEDOT/PSS and a copolymer of vinylacetate and ethylene according to the first aspect, wherein the at least one probe is adapted to be placed in electrical contact with a surface of a patient's tooth;

a second electrode adapted to be placed in electrical contact with another part of the body of the patient;

an alternating current source adapted for passing an alternating electrical current between said at least one probe electrode and said second electrode;

impedance measurement means for measuring the electrical impedance between the at least one probe electrode and the second electrode to said electrical current;

wherein said alternating current source is a variable frequency alternating current source whereby the frequency of the alternating current applied to the tooth may be varied over a predetermined frequency range and the impedance measurement means is adapted to measure impedancies corresponding to a plurality of frequency values within said range.

By monitoring the impedance values, abnormalities in the detected signal may be used to detect and locate dental caries.

### BRIEF DESCRIPTION OF THE DRAWINGS

Embodiments of the present invention will now be described, by way of example only, with reference to the accompanying drawings in which:

FIG. 1 is a schematic representation of apparatus used for the detection of dental caries.

### DETAILED DESCRIPTION

Materials

1. PEDOT/PSS was obtained as an aqueous dispersion from Bayer Germany. Characteristic properties of PEDOT/PSS are shown in Table 1 below.

TABLE 1
Characteristic properties of PEDOT/PSS

| | Particle Size | Solids | Density | Viscosity | |
|---|---|---|---|---|---|
| Sample | (microns) | (%) | (g/cc) | (mPa · s) | pH |
| PEDOT/ | 0.08-1.0 | 1.2-1.4 | 1.003 | 60-100 | 1.5-2.5 |
| PSS* | | | | | |

*Molar Ratio 1:2.5 dark blue odourless liquid conductivity up to 10 S/cm (depending upon the type of coating formulation)

2. The copolymers used in the formulation were provided by Clariant, Germany. Characteristic properties of the copolymer, a non-plasticised aqueous dispersion based on vinylacetate and ethylene are shown in Table 2 below.

TABLE 2
Characteristic properties of the copolymer
vinylacetate and ethylene.

| | Particle Size | Solids | Density | Viscosity | |
|---|---|---|---|---|---|
| Sample | (microns) | (%) | (g/cc) | (mPa · s) | pH |
| Copolymer 1 | 0.3-1.2 | 55 | 1.06 | 2,500 | 4.25 |
| Copolymer 2 | 0.3-3.0 | 55 | — | 14,000 | 4.25 |

Method

Two conducting polymer blends were formulated:

Type 1-PEDOT/PSS-copolymer blend; and

Type 2-PEDOT/PSS-solvent-copolymer blends.

Tables 3 and 4 shown below represent the specific recipes for each of these blends and relevant properties.

TABLE 3
Resistance values for PEDOT/PSS - Copolymer 1 blends

| | | Composition | | | | Resistance | |
|---|---|---|---|---|---|---|---|
| | | (wt. grms) | | | Thick | k-Ohm | |
| Blend | Sample | ICP | Solvent | Copoly1 | (mm) | Untreated | Treated |
| Type | 1 | 0.3 | — | 0.018 | 0.02 | 320 | — |
| I | | | | | | | |
| Type | 2 | 0.45 | — | 0.018 | 0.03 | 238 | — |
| I | | | | | | | |
| Type | 3 | 0.6 | — | 0.018 | 0.04 | 170 | — |
| I | | | | | | | |
| Type | 4 | 0.4 | 0.05 | 0.02 | 0.02 | 2.3 | 1.0 |
| II | | | | | | | |
| Type | 5 | 0.6 | 0.05 | 0.02 | .04 | 8.0 | 1.2 |
| II | | | | | | | |
| Type | 6 | 0.6 | 0.05 | 0.018 | 0.04 | 5.0 | — |
| II | | | | | | | |
| Type | 7 | 0.6 | 0.05 | 0.016 | 0.04 | 3.0 | 0.5 |
| II | | | | | | | |

TABLE 4
Resistance values for PEDOT/PSS - Copolymer 2 blends

| | | Composition | | | | Resistance | |
|---|---|---|---|---|---|---|---|
| | | (wt. grms) | | | Thick | k-Ohm | |
| Blend | Sample | ICP | Solvent | Copoly2 | (mm) | Untreated | Treated |
| Type | 1 | 0.45 | — | 0.018 | 0.03 | 238 | — |
| I | | | | | | | |
| Type | 2 | 0.45 | 0.04 | 0.018 | 0.03 | 10 | 0.3 |
| II | | | | | | | |
| Type | 3 | 0.45 | 0.08 | 0.018 | 0.03 | 4.6 | — |
| II | | | | | | | |
| Type | 4 | 0.45 | 0.08 | 0.024 | 0.03 | 7.6 | — |
| II | | | | | | | |
| Type | 5 | 0.45 | 0.05 | 0.009 | 0.03 | 8.1 | 0.34 |
| II | | | | | | | |
| Type | 6 | 0.45 | 0.05 | 0.016 | 0.03 | 8.4 | 0.17 |
| II | | | | | | | |

The type 1 blends were formed by mixing an aqueous dispersion of PEDOT/PSS with either copolymer 1 or copolymer 2 using mortar and pestle to obtain a homogenous blend. A known quantity of the resulting blend was cast onto cellulose acetate plastic strips (obtained from Associated Dental Products Limited, UK) with a syringe to obtain a uniform coating. After casting, the substrates were cured overnight at room temperature in a fume hood.

The procedure was repeated for type II blends except that the aqueous dispersion of PEDOT/PSS was mixed first with formic acid (96%, Aldrich) which is used as a solvent and then with the copolymer to obtain a homogenous blend.

The coated substrates for both type I and type II blends were then weighed to determine the conductive polymer content. The thickness of the coatings were then evaluated using vernier callipers.

Each modified substrate of the type I and type II form were treated with about 0.1 M magnesium sulphate dissolved in aqueous acid for about 4 hours. The treated substrates were then rinsed successively with water to remove excess salt, rinsed with ethanol and acetone and finally kept in an air oven at 40° C. until the substrates were completely dry.

Surface resistance of the substrates was measured using a four-point probe technique at various locations on each substrate. The test results for copolymers 1 and 2 are shown in Tables 3 and 4, respectively.

### DISCUSSION

PEDOT/PSS is initially obtained as an aqueous dispersion in water. In this dispersion, PEDOT, the charge transporting species is in its oxidised state i.e. doped form. The counter-ion PSS is in excess with respect to the positively charged PEDOT chain. The ratio of PEDOT:PSS is about 1:2.5. Although not wishing to be bound by theory, this leads to the formation of a non-stoichiometric soluble polyelectrolyte complex [7] defined by the PSS random coil with PEDOT chains ionically linked alongside and the area between the grains consisting of neutral PSS. When the dispersion is cast onto a substrate, a thin polymer film is formed with a morphological feature characterised by a non-homogeneous distribution of PEDOT and PSS species within the conducting grains surrounded by a non-conductive PSS shell [8]. This illustrates the key role played by granularity and disorder in the conduction of conjugated polymers [9,10].

Incorporation of a small quantity of the vinylacetate/ethylene copolymer to PEDOT/PSS adds a non-conducting barrier which increases the resistance of the deposited films as observed in Tables 3 and 4 for the type I blends. On the other hand when the PEDOT/PSS is first mixed with formic acid and then with the vinylacetate/ethylene copolymer, as in the case of type II blends, a dramatic decrease in resistance of the deposited films by a factor of over 200 was observed when compared to type I blends. This indicates the particularly significant role of the solvent in changing the morphology of the deposited films resulting in enhanced conducting properties.

Tables 3 and 4 also show that when the coated strips of type II blends were post-treated with magnesium salt in an aqueous acid, a further fine tuning of the resistance by a factor of 10 was achieved.

The coated strips made of type II blends combine high conductivity with good flexibility and mechanical stability. Furthermore, tensile tests carried out on the strips indicate no exfoliation of the coated layer even at the breaking point, indicating good adhesion onto the surface. This was further confirmed by the ‘cross hatch’ test which conforms with BS 3900 Eb to assess the adhesion of the deposited coatings.

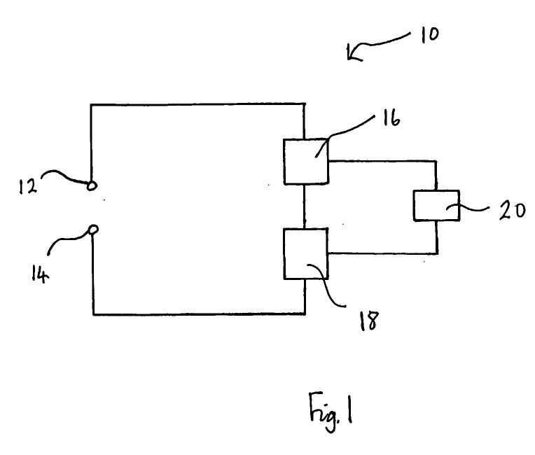

FIG. 1 is a schematic representation of apparatus, generally designated 10, which is used for the electronic detection of dental caries. The electronic detection apparatus 10 comprises a first electrode probe 12 which is placed in electrical contact with a patient's tooth and a second electrode 14 which is placed in electrical contact with another part of the body of the patient. An alternating current is passed from an a.c. source 16 between the probe 12 and the second electrode 14.

The first electrode probe 12 comprises a plastics substrate of cellulose acetate which has a coating formed by adding a mixture of PEDOT/PPS to a copolymer of vinylacetate and ethylene to form an intrinsically conducting polymer (ICP) blend. To increase the conductivity of the coated substrate, the PEDOT/PSS is first mixed with formic acid prior to the addition of the copolymer of vinylacetate and ethylene. The coated substrate is also treated with about a 0.1 M magnesium sulphate salt solution dissolved in aqueous acid and thereafter dried in an oven at about 40° C. This salt solution treatment is found to increase the conductivity by a factor of 10.

By varying the frequency of the alternating a.c. current over a predetermined frequency range, the electrical impedance between the probe 12 and the second electrode 14 is measured by electrical impedance measurement means 18. By analysing the changes in electrical impedance using data processing and control means 20, an assessment of the condition of a tooth may be made and an assessment if there are any dental caries present.

### REFERENCES

[1] S. Ghosh, Olle Inganas, Synth. Met. 121 (2001) 1321
[2] G. K. Elyashevich, V. K. Lavrentyev, I. S. Kuryndin, E. Yu. Rosova, Synth. Met. 119 (2001) 277
[3] L. B. Groendaal, F. Jonas, D. Freitag, H. Pielartzik, J. R. Reynolds, Adv. Mater. 12 (2000) 481
[4] J. C. Gustafson, B. Liedberg, O. Inganas, Sol. State Ionics 69 (1994) 145
[5] L. Groendall, G. Zotti, F. Jonas, Synth. Met. 118 (1-3) (2001) 105
[6] H. W. Heuer et al., Adv. Funct. Mater. 12 No. 2 (2002) 83
[7] S. Ghosh, J. Rasmusson, O. Inganas, Adv. Mater. 10 (1998) 1097
[8] G. Grezynski, T. Kugler, W. R. Salaneck, Thin Solid Films 354 (1999) 129
[9] V. N. Progodin, A. J. Epstein, Synth. Met 125 (2001) 43
[10] J. P. Travers, B. Sixou, D. Berner, A. Wolter, P. Rannou, B. Beau, B. Pepin-Donat, C. Barthet, M. Gugliemi, N. Merilliod, B. Gilles, D. Djurado, A. J. Attias, M. Vautrin, Synth. Met. 101 (1999) 359

1. An intrinsically conducting polymer (ICP) blend obtainable by adding:
a. a mixture of poly (3,5-ethylenedioxythiophene) and poly(4-styrenesulphonate) (i.e. PEDOT/PSS); to
b. a copolymer of vinylacetate and ethylene to thereby form the intrinsically conducting polymer (ICP) blend.

2. An intrinsically conducting polymer (ICP) blend according to claim 1 wherein the viscosity of the PEDOT/PSS is about 60 to about 100 mPa·s.

3. An intrinisically conducting polymer (ICP) blend according to any of claims 1 or 2 wherein the amount of PSS present is in excess of the amount of PEDOT.

4. An intrinsically conducting polymer (ICP) according to any preceding claim wherein the ratio of PEDOT:PSS ranges from about 1:1.1 to about 1:5, from about 1:1.3 to about 1:2 or about 1:2.5.

5. An intrinsically conducting polymer (ICP) according to any preceding claim wherein the PEDOT/PSS is in a liquid form and has a concentration of about 1-2% by weight, about 1-10% by weight or about 3% by weight.

6. An intrinsically conducting polymer (ICP) according to any preceding claim wherein the PEDOT/PSS is dissolved in a solvent such as water.

7. An intrinsically conducting polymer (ICP) according to any preceding claim wherein the ratio of vinylacetate:ethylene is about 80:20.

8. An intrinsically conducting polymer (ICP) according to any preceding claim wherein the particle size of the vinylacetate:ethylene mixture is about 0.1-10 microns, 0.1-5 microns, 0.3-3.0 microns or about 0.3-1.2 microns.

9. An intrinsically conducting polymer (ICP) according to any preceding claim wherein the viscosity of the vinylacetate:ethylene copolymer is about 1,000-40,000 mPa·s, about 1-20,000 mPa·s, about 14,000 mPa·s or about 2,500 mPa·s.

10. An intrinsically conducting polymer (ICP) according to any preceding claim wherein the vinylacetate:ethylene copolymer mixture is acidic and has a pH of about 2-6, about 3-5 or about 4.25.

11. An intrinsically conducting polymer (ICP) according to any preceding claim wherein prior to mixing the PEDOT/PSS and the copolymer of vinylacetate and ethylene, the PEDOT/PSS is mixed with an acid such as a carboxylic acid.

12. An intrinsically conducting polymer (ICP) according to claim 11 wherein the carboxylic acid is selected from any C₁-C₂₀ carboxylic acid, or combination thereof.

13. An intrinsically conducting polymer (ICP) according to claim 12 wherein the carboxylic acid is any of methanoic acid, ethanoic acid, propanoic acid, butanoic acid, pentanoic acid, hexanoic acid, heptanoic acid and octanoic acid.

14. An intrinsically conducting polymer (ICP) according to any preceding claim wherein the ICP formed by mixing the PEDOT/PSS and the copolymer of vinylacetate and ethylene forms a substantially homogenous blend.

15. A coated product wherein the coated product comprises a substrate with a coating of an intrinsically conducting polymer (ICP) blend comprising PEDOT/PSS and a copolymer of vinylacetate and ethylene according to any of claims 1 to 14.

16. A coated product according to claim 15 wherein the coating is found to adhere strongly to the substrate, has good mechanical stability and is resistant to exfoliating.

17. A coated product according to any of claims 15 or 16 wherein the substrate is man made such as cellulose acetate, polypropylene, nylon or a biopolymer produced from renewable resources such as poly-lactic acid, poly-glycollic acid, or any copolymer thereof.

18. A coated product according to any of claims 15 to 17 wherein the coating has a thickness of about 0.001 to 0.5 mm, about 0.01 to 0.1 mm, or about 0.02, 0.03 and 0.04 mm.

19. A coated product according to any of claims 15 to 18 wherein the resistance of a coated part of the coated substrate may be about 0.1 to 500 k-ohm.

20. A coated product according to any of claims 15 to 19 wherein the coated substrate is treated with a metal salt solution dissolved in aqueous acid.

21. A coated product according to claim 20 wherein the metal salt solution is magnesium sulphate.

22. A coated product according to any of claims 20 or 21 wherein the concentration of the salt solution is about 0.01 to 5 M, about 0.05 to 1 M or about 0.1 M.

23. A coated product according to claim 20 wherein the aqueous acid is a short chain carboxylic acid such as formic acid.

24. A coated product according to claim 23 wherein the volume ratio of the carboxylic acid such as formic acid and water is about 1:1 to 1:4.

25. A coated product according to any of claims 20 to 24 wherein the treated coated substrate is rinsed successively with water to remove excess salt, followed by ethanol and acetone.

26. A coated product according to any of claims 20 to 25 wherein treating the coated substrate with a metal salt solution dissolved in aqueous acid has the effect of ‘fine tuning’ the surface and decreases the surface resistance to about less than 5 k-ohms, less than 1 k-ohms or less than about 0.5 k-ohms.

27. A method of forming a coated substrate wherein coating material is formed by adding PEDOT/PSS to a copolymer of vinylacetate and ethylene to form an intrinsically conducting polymer (ICP) blend according to any of claims 1 to 14 and depositing the intrinsically conductive polymer (ICP) blend onto a substrate.

28. A method according to claim 27 wherein the ICP blend is deposited by any suitable means such as spraying, brushing, or using a dropper such as a syringe.

29. An electrode comprising a coated substrate wherein the coating of the coated substrate is an intrinsically conducting polymer (ICP) blend comprising PEDOT/PSS and a copolymer of vinylacetate and ethylene according to any of claims 1 to 14.

30. Use of an electrode according to claim 29 in dental apparatus for the detection of caries.

31. Use of an electrode according to claim 29 as a thin, intermediate layer between an anode and a light emitting layer of organic polymers wherein the PEDOT/PSS copolymer blends polarise the otherwise rough ITO surface for subsequent organic layer deposition and increase the anode work function, thus facilitating hole injection.

32. Use according to claim 31, wherein the anode is indium-tin oxide (ITO).

33. Use of an intrinsically conducting polymer (ICP) blend according to any of claims 1 to 14 in forming conductive composite materials by depositing or impregnating the ICP blends onto natural or synthetic fabrics.

34. Use of an intrinsically conducting polymer (ICP) according to claim 33 in the formation of an electrode.

35. Dental apparatus for the detection of dental caries comprising:
at least one probe electrode comprising a coated substrate wherein the coating of the coated substrate is an intrinsically conducting polymer of PEDOT/PSS and a copolymer of vinylacetate and ethylene according to the first aspect, wherein the at least one probe is adapted to be placed in electrical contact with a surface of a patient's tooth;
a second electrode adapted to be placed in electrical contact with another part of the body of the patient;
an alternating current source adapted for passing an alternating electrical current between said at least one probe electrode and said second electrode;
impedance measurement means for measuring the electrical impedance between the at least one probe electrode and the second electrode to said electrical current;
wherein said alternating current source is a variable frequency alternating current source whereby the frequency of the alternating current applied to the tooth may be varied over a predetermined frequency range and the impedance measurement means is adapted to measure impedancies corresponding to a plurality of frequency values within said range.

36. Dental apparatus according to claim 35, wherein by monitoring the impedance values, abnormalities in the detected signal are used to detect and locate dental caries.
